(19) United States
(12) Patent Application Publication
(10) Pub. No.: US 2026/0319462 A1
(43) Pub. Date: Oct. 15, 2026

(54) METHOD AND APPARATUS FOR METHOD OF MAPPING THE HEIGHT OF A SURFACE ON A SUBSTRATE

(71) Applicant: ASML Netherlands B.V., Veldhoven (NL)

(72) Inventors: Brian Johannes Magdalena REULEN, Kelpen-Oler (NL); Aleksei Levan NAZARIAN, Eindhoven (NL); Martin Jules Marie-Emile DE NIVELLE, Waalre (NL)

(73) Assignee: ASML Netherlands B.V., Veldhoven (NL)

(21) Appl. No.: 19/485,504

(22) PCT Filed: May 17, 2024
(86) PCT No.: PCT/EP2024/063825

§ 371 Date: Nov. 18, 2025

(30) Foreign Application Priority Data
Jun. 9, 2023 (EP) 23178340.8

(51) Int. Cl. G05B 19/4099

(52) U.S. Cl. CPC G05B 19/4099; G05B 2219/45028

(57) ABSTRACT

An apparatus and method for mapping the height of a surface on a substrate. The method comprises: controlling a movement mechanism to generate a single stroke of movement of a measurement location of a plurality of measurement spots of a radiation beam over the surface of the substrate, the substrate supported by a non-rotatable substrate table, wherein the movement is in a plane of the substrate, the plurality of measurement spots are incident on the surface of the substrate by a level sensor for mapping the height of the substrate, and said stroke follows a curved path to map the entire surface of the substrate.

### CROSS-REFERENCE TO RELATED APPLICATIONS

This application claims priority of EP application 23178340.8 which was filed on 9 Jun. 2023, and which is incorporated herein in its entirety by reference.

### FIELD

The present invention relates to a method and apparatus for mapping the height of a surface on a substrate. The present invention has particular application in the field of lithography.

Such a substrate may comprise a silicon wafer coated with a photoresist.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) of a patterning device (e.g., a mask) onto a layer of radiation-sensitive material (resist) provided on a substrate (e.g., a wafer).

As semiconductor manufacturing processes continue to advance, the dimensions of circuit elements have continually been reduced while the amount of functional elements, such as transistors, per device has been steadily increasing over decades, following a trend commonly referred to as ‘Moore’s law'. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm. A lithographic apparatus, which uses extreme ultraviolet (EUV) radiation, having a wavelength within a range of 4 nm to 20 nm, for example 6.7 nm or 13.5 nm, may be used to form smaller features on a substrate than a lithographic apparatus which uses, for example, radiation with a wavelength of 193 nm.

Before exposure of a wafer to patterned radiation in a lithographic apparatus, a topography of the wafer may be determined using apparatus that may be referred to as a level sensor. This measurement of the topography of the wafer may be performed within the lithographic apparatus, for example once the wafer has been clamped to a wafer stage. This information can be used during subsequent exposure of the wafer in order to keep the part of the wafer that is being exposed in a plane of best focus.

Known leveling strategies project a radiation beam onto a plurality of measurement spots at a measurement location on the surface of a wafer and measure the surface of a wafer by moving the measurement location in straight strokes along a scanning exposure direction (e.g. in a y-direction, along the substrate surface plane) with constant velocity, or with non-constant velocity in a single direction.

It may be desirable to provide new methods and/or apparatus for determining a topography of a wafer that may at least partially address one or more problems associated with existing arrangements, whether identified herein or otherwise.

### SUMMARY

The inventors have identified a need to reduce the time taken to map the height of a surface on a substrate. According to one aspect of the present invention there is provided a method of mapping the height of a surface on a substrate, the method comprising: controlling a movement mechanism to generate a single stroke of movement of a measurement location of a plurality of measurement spots of a radiation beam over the surface of the substrate, the substrate supported by a non-rotatable substrate table, wherein the movement is in a plane of the substrate, the plurality of measurement spots are incident on the surface of the substrate by a level sensor for mapping the height of the substrate, and said stroke follows a curved path to map the entire surface of the substrate.

In embodiments of the present disclosure, no time is wasted scanning outside of the surface of the substrate. In particular, the level sensor constantly (without interruption) scans the surface of the substrate during a measurement. Furthermore, no time is wasted on losing and gaining speed between strokes as incurred in some known methods. Thus, the time taken to map the height of a surface on a substrate is advantageously reduced.

The method may comprise controlling the movement mechanism so that the measurement location follows a spiral path.

The method may comprise controlling the movement mechanism so that the measurement location originates from an edge of the substrate and spirals radially inwards towards a substantially central location on the surface of the substrate.

The method may comprise controlling the movement mechanism so that the measurement location originates from a substantially central location on the surface of the substrate and spirals radially outwards towards an edge of the substrate.

The method may comprise controlling the movement mechanism to move the measurement location over the surface of the substrate with non-constant velocity and non-constant acceleration during the stroke.

The movement mechanism may be coupled to the non-rotatable substrate table, and the method may comprise controlling the actuators to control movement of the non-rotatable substrate table to move the measurement location.

The movement mechanism may be coupled to a radiation source which emits the radiation beam, and the method may comprise controlling the movement mechanism to control movement of the radiation source to move the measurement location.

The movement mechanism may be coupled to projection optics operable to form the plurality of measurement spots, and the method may comprise controlling the movement mechanism to control movement of the projection optics to move the measurement location.

The method may comprise receiving sensor data obtained by the level sensor during the movement of the measurement location; and determining the height of the surface on the substrate based on the sensor data.

The stroke may follow a continually curved path.

According to another aspect of the present invention there is provided an apparatus for mapping the height of a surface on a substrate, the apparatus comprising: a non-rotatable support table for supporting a substrate; projection optics arranged to direct a radiation beam to be incident on the surface of the substrate a movement mechanism controllable to generate a single stroke of movement of a measurement location of a plurality of measurement spots of the radiation beam over the surface of the substrate, and at least one processor configured to control the movement mechanism to generate the single stroke of movement of the measurement location, wherein the movement is in a plane of the substrate, and said stroke follows a curved path to map the entire surface of the substrate.

The at least one processor may be configured to control the movement mechanism so that the measurement location originates from an edge of the substrate and spirals radially inwards towards a substantially central location on the surface of the substrate.

The at least one processor may be configured to control the movement mechanism so that the measurement location originates from a substantially central location on the surface of the substrate and spirals radially outwards towards an edge of the substrate.

The at least one processor may be configured to control the movement mechanism to move the measurement location over the surface of the substrate with non-constant velocity and non-constant acceleration during the stroke.

The movement mechanism may be coupled to the non-rotatable substrate table, and the at least one controller is configured to control the movement mechanism to control movement of the non-rotatable substrate table to move the measurement location.

The movement mechanism may be coupled to a radiation source which emits the radiation beam, and the at least one processor may be configured to control the movement mechanism to control movement of the radiation source to move the measurement location.

The movement mechanism may be coupled to projection optics operable to form the plurality of measurement spots, and the at least one processor may be configured to control the movement mechanism to control movement of the projection optics to move the measurement location.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 is a schematic illustration of a level or height sensor which may form part of the lithographic apparatus shown in FIG. 1;

FIG. 3 illustrates the path taken by a measurement location in a known technique for mapping the height of a surface on a substrate;

FIG. 4 is a schematic representation of an apparatus for mapping the height of a surface on a substrate, which may form part of the lithographic apparatus shown in FIG. 1 and which may implement the method shown in FIG. 5.

FIG. 5 illustrates a method of mapping the height of a surface on a substrate;

FIG. 6 depicts a measurement location comprising a plurality of measurement spots;

FIG. 7 illustrates an example path taken by a measurement location of a plurality of measurement spots of a radiation beam, over the surface of a substrate;

FIG. 8 illustrates another example path taken by a measurement location of a plurality of measurement spots of a radiation beam, over the surface of a substrate;

FIG. 9 illustrates a non-uniform radiation dose from a radiation beam on a surface of a substrate after the entire surface has been mapped;

FIG. 10 depicts the non-constant velocity of the measurement location over the surface of a substrate during a scan of the substrate; and

FIG. 11 depicts the non-constant acceleration of the measurement location over the surface of a substrate during a scan of the substrate.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

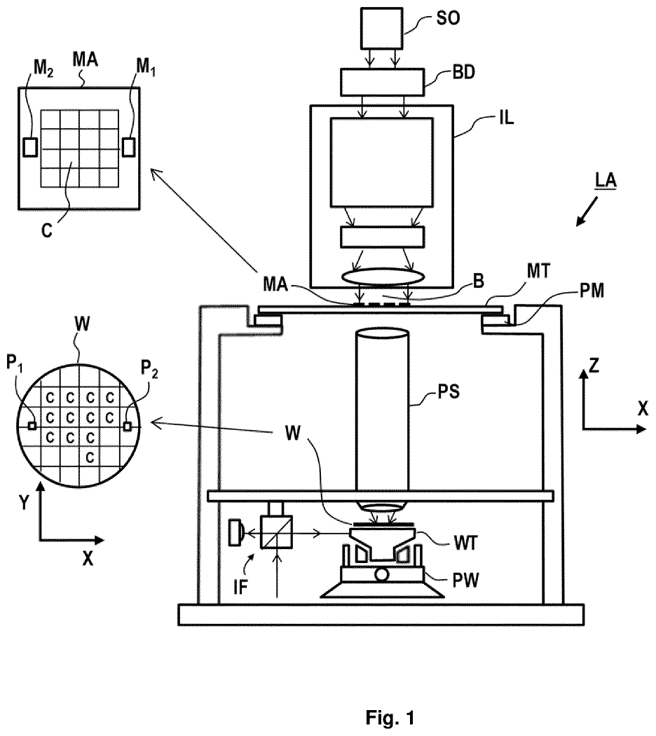

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W-which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W, on the other substrate support WT, is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions C. Substrate alignment marks P1, P2 are known as scribe-lane alignment marks when these are located between the target portions C.

To clarify the invention, a Cartesian coordinate system is used. The Cartesian coordinate system has three axes, i.e., an x-axis, a y-axis and a z-axis. Each of the three axes is orthogonal to the other two axes. A rotation around the x-axis is referred to as an Rx-rotation. A rotation around the y-axis is referred to as an Ry-rotation. A rotation around the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

A topography measurement system, level sensor or height sensor, and which may be integrated in the lithographic apparatus, is arranged to measure a topography of a top surface of a substrate (or wafer). A map of the topography of the substrate, also referred to as height map, may be generated from these measurements indicating a height of the substrate as a function of the position on the substrate. This height map may subsequently be used to correct the position of the substrate during transfer of the pattern on the substrate, in order to provide an aerial image of the patterning device in focus on the substrate. It will be understood that “height” in this context refers to a dimension broadly out of the plane to the substrate (also referred to as Z-axis). Typically, the level or height sensor performs measurements at a fixed location (relative to its own optical system) and a relative movement between the substrate and the optical system of the level or height sensor results in height measurements at locations across the substrate.

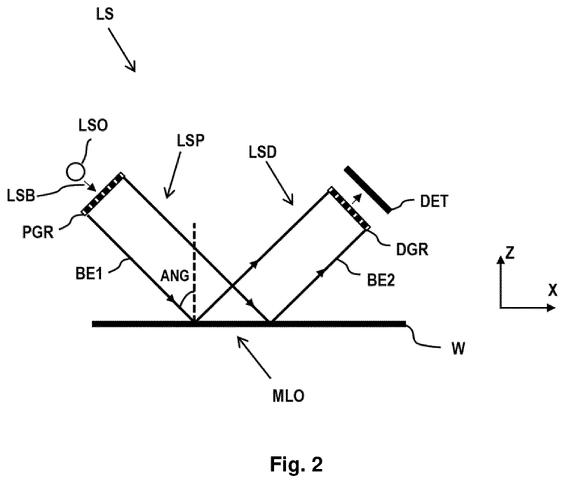

An example of a level or height sensor LS as known in the art is schematically shown in FIG. 2, which illustrates only the principles of operation. In this example, the level sensor LS comprises an optical system, which includes a projection unit LSP and a detection unit LSD. The projection unit LSP comprises a radiation source LSO providing a beam of radiation LSB which is imparted with a pattern by a projection grating PGR of the projection unit LSP. The projection grating PGR may alternatively be referred to as a patterning device PGR. The radiation source LSO may be, for example, a narrowband or broadband radiation source, such as a supercontinuum light source, polarized or non-polarized, pulsed or continuous, such as a polarized or non-polarized laser beam. The radiation source LSO may include a plurality of radiation sources having different colors, or wavelength ranges, such as a plurality of LEDs. The radiation source LSO of the level sensor LS is not restricted to visible radiation, but may additionally or alternatively encompass UV and/or IR radiation and any range of wavelengths suitable to reflect from a surface of a substrate.

The projection grating PGR is a periodic grating comprising a periodic structure resulting in a beam of radiation BE1 having a periodically varying intensity. The beam of radiation BE1 with the periodically varying intensity is directed towards a measurement location MLO on a substrate W having an angle of incidence ANG with respect to an axis perpendicular (Z-axis) to the incident substrate surface between 0 degrees and 90 degrees, typically between 70 degrees and 80 degrees. The measurement location MLO may alternatively be referred to as the beam spot region MLO. At the measurement location MLO, the patterned beam of radiation BE1 is reflected by the substrate W (indicated by arrows BE2) and directed towards the detection unit LSD.

In order to determine the height level at the measurement location MLO, the level sensor further comprises a detection system comprising a detection grating DGR, a detector DET and a processing unit (not shown) for processing an output signal of the detector DET. The detection grating DGR may be identical to the projection grating PGR. The detector DET produces a detector output signal indicative of the light received, for example indicative of the intensity of the light received, such as may be output by a photodetector, or representative of a spatial distribution of the intensity received, such as may be output by a camera or sensor array. The detector DET may comprise any combination of one or more detector types.

By means of triangulation techniques, the height level at the measurement location MLO can be determined. The detected height level is typically related to the signal strength as measured by the detector DET, the signal strength having a periodicity that depends, amongst others, on the design of the projection grating PGR and the (oblique) angle of incidence ANG.

The projection unit LSP and/or the detection unit LSD may include further optical elements, such as lenses and/or mirrors, along the path of the patterned beam of radiation between the projection grating PGR and the detection grating DGR (not shown).

In an embodiment, the detection grating DGR may be omitted, and the detector DET may be placed at the position where the detection grating DGR is located. Such a configuration provides a more direct detection of the image of the projection grating PGR.

In order to cover the surface of the substrate W effectively, a level sensor LS may be configured to project an array of measurement beams BE1 onto the surface of the substrate W, thereby generating an array of measurement areas MLO or spots covering a larger measurement range.

Various height sensors of a general type are disclosed for example in U.S. Pat. No. 7,265,364 and U.S. Pat. No. 7,646,471, both incorporated by reference. A height sensor using UV radiation instead of visible or infrared radiation is disclosed in US2010233600A1, incorporated by reference. In WO2016102127A1, incorporated by reference, a compact height sensor is described which uses a multi-element detector to detect and recognize the position of a grating image, without needing a detection grating.

In general, the detection unit LSD may be arranged such that the reflected radiation BE2 is split into first and second portions and the height of the substrate W is determined by combining the intensities of the first and second portions. For example, the height may be determined as a differential measurement. Advantageously, with such an arrangement, the determination of the height of the substrate W can be substantially independent of the intensity of the radiation beam BE1. In practice, the splitting of the radiation into first and second portions may be achieved in a number of different ways.

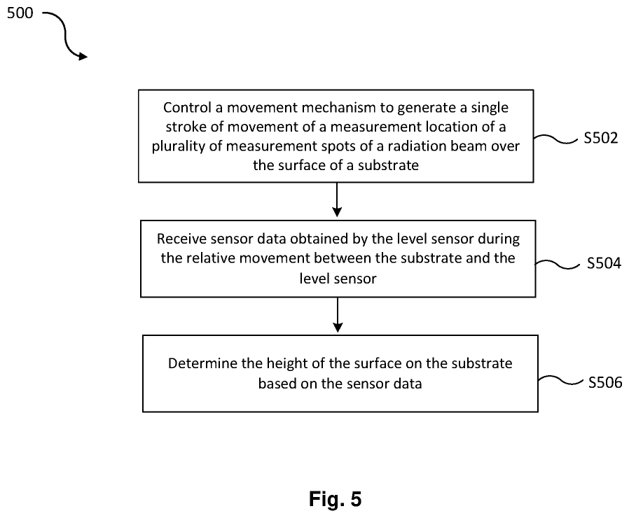

For example, in some known arrangements, a combination of a polarizer and a shear plate (for example in the form of a Wollaston prism) are used to form two laterally shifted images of the projection grating PGR (each having a different polarization state) on a detection grating DGR. An example of such an arrangement is shown schematically in FIG. 5 of US2010233600A1. For example, the projection grating PGR may have a pitch P and a duty cycle of 50% such that the beam of radiation BE1 having a periodically varying intensity comprises a plurality of lines having a thickness of P/2, adjacent lines being separated by P/2. The polarizer and a shear plate are arranged to form two images of the projection grating PGR (each having a different polarization state) on the detection grating DGR, one image being laterally shifted relative to the other by P/2. Downstream of the detection grating DGR the two separate polarization states are each directed to a different detector. The height of the substrate W is determined as being proportional to the difference in the intensities of the two separate polarization states.

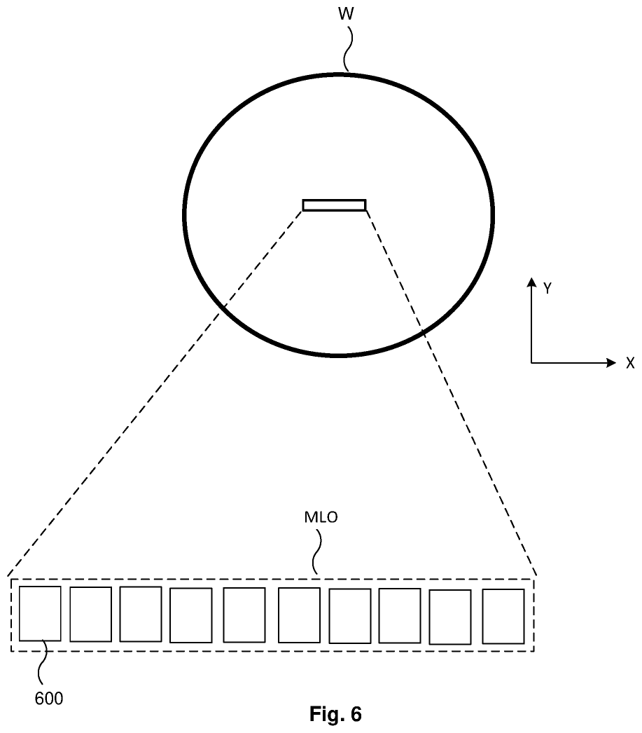

In some other known arrangements, rather than splitting the reflected radiation BE2 using two images of the projection grating PGR but having different polarization states, a single image of the projection grating PGR is formed on splitting optics that is arranged to split that single image into first and second portions. Examples of such arrangements are shown schematically in FIG. 6 of US2010233600A1 and FIG. 2 of WO2016102127A1. For example, such arrangements generally comprise splitting optics that is arranged to split the reflected radiation into first and second portions. The splitting optics may be a ruled grating with a triangular grating profile which acts as a series of wedges or prisms to redirect the reflected radiation BE2 (according to Snell's law). Such splitting optics may be considered to comprise a plurality of prisms and the image of each line of the projection grating PGR may be imaged onto one of the plurality of generally triangular prisms such that a first portion of the line is incident in a first surface of the prism and a second portion of the line is incident in a second surface of the prism. The first portion of the line is directed to the first detector and the second portion of the line is directed to the second detector. As the line moves relative to the prism (as a result of a change in height of the substrate W), the amount of radiation directed to each of the detectors changes. Embodiments of the present disclosure have particular application for level sensors using splitting optics of this type.

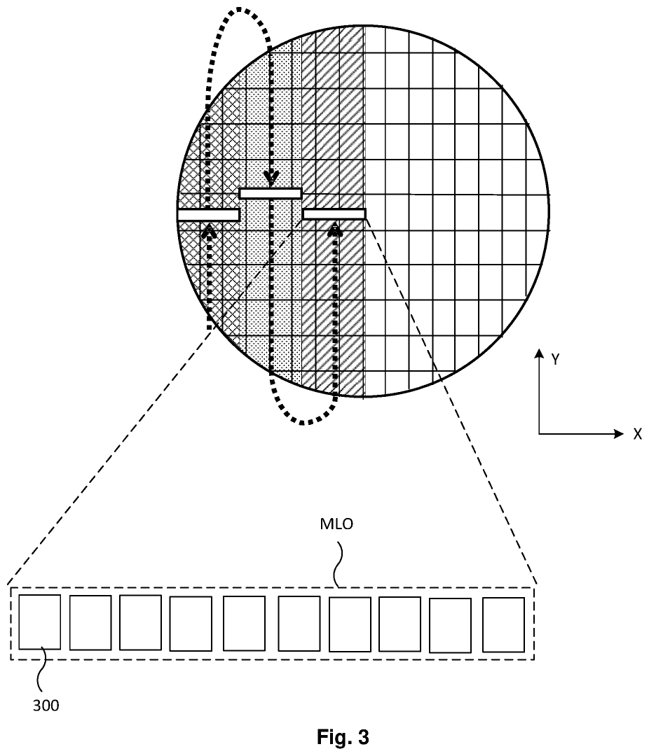

FIG. 3 illustrates the path taken by a measurement location MLO in a known technique for mapping the height of a surface on a substrate. FIG. 3 is a top view of an upper surface of a substrate.

The measurement location MLO is where a beam of radiation is incident on the surface of a substrate W at plurality of measurement spots 300.

As shown in FIG. 3, known techniques measure the surface of a substrate by moving the measurement location (relative to the substrate) in multiple (e.g. six) straight strokes along a scanning exposure direction (e.g. in a y-direction, along the substrate surface plane) with constant velocity, or with non-constant velocity in a single direction. During each of the strokes a linear scan across the substrate W is performed during which measurements are obtained with a level sensor. Moving the substrate W relative to the measurement location MLO may comprise moving a substrate table WT. As shown in FIG. 3, the turns and accelerations of the substrate table WT are made while the plurality of measurement spots 300 are not incident on the substrate. Thus, in between the strokes the substrate table WT is moved during which measurements are not obtained with a level sensor. Accelerations of the substrate table WT in the y-direction may be allowed to happen during the stroke measurements. By allowing the substrate table WT to accelerate in the y-direction during the measurements the turns outside the substrate can be shortened and a higher maximum velocity on the wafer can be achieved, resulting in a faster wafer map measurement. The inventors have identified how to provide further improvements in the time taken to scan the entire surface of a substrate.

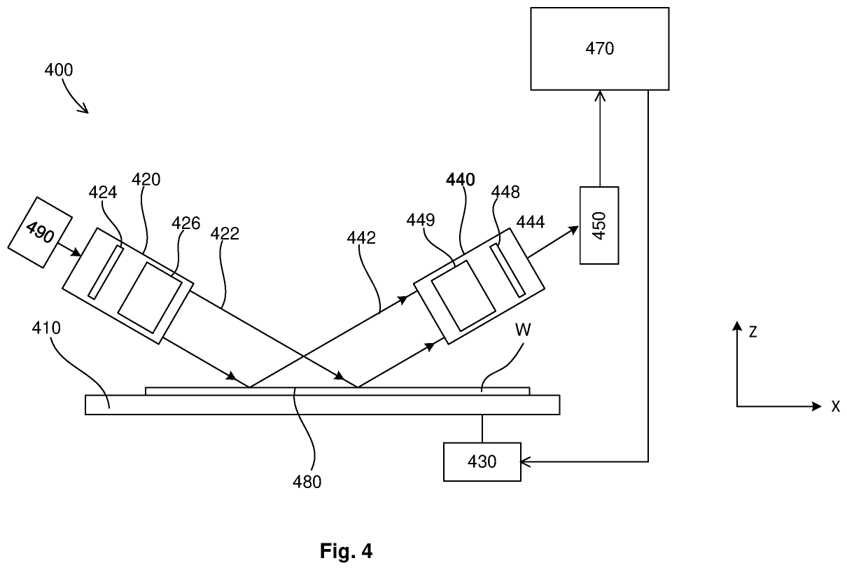

Some embodiments of the present disclosure relate to an apparatus for mapping the height of a surface on a substrate (e.g., a resist coated wafer) W. An embodiment of such an apparatus 400 is shown in FIG. 4. The apparatus 400 may be referred to as a level sensor. The apparatus 400 may form part of a lithographic apparatus LA of the type shown in FIG. 1 and described above. The apparatus 400 is generally of the form of the level sensor LS shown in FIG. 2.

The apparatus 400 comprises: a non-rotatable substrate table 410; projection optics 420; a movement mechanism 430; detection optics 440; a detector 450; and at least one processor 470.

The non-rotatable substrate table 410 is suitable for supporting the substrate W. In embodiments of the present invention, a single support (i.e. the non-rotatable substrate table 410) is used for supporting the substrate W.

The projection optics 420 is operable to form a first image of a pattern on a measurement location MLO with a radiation beam 422. The projection optics 420 is generally equivalent to the projection unit LSP shown in FIG. 2. The projection optics 420 may, for example, comprise: a projection patterning device 424; and first imaging optics 426 arranged to form an image of the projection patterning device 424 on the measurement location MLO. The projection patterning device 424 may comprise a grating. The grating may comprise a plurality of lines. The lines may be of uniform thickness. The grating may have a 50% duty cycle. The projection patterning device 424 may be generally equivalent to the projection grating PGR shown in FIG. 2 and described above.

In some embodiments, the apparatus 400 may further comprise a radiation source 490 operable to produce the radiation beam 422.

The movement mechanism 430 is controllable such that the measurement location MLO is moved relative to the substrate W. The movement mechanism 430 may comprise one or more actuators. A processor 470 is coupled to the movement mechanism 430 and is configured to control the movement mechanism 430 (e.g. the one or more actuators) to generate a single stroke of movement of the measurement location MLO over the surface of the substrate W.

As shown in FIG. 4, the movement mechanism 430 may be coupled to the non-rotatable substrate table 410, and the processor 470 may be configured to control the movement mechanism 430 to move the non-rotatable substrate table 410 so as to move the substrate W supported by the non-rotatable substrate table 410 through the measurement location MLO. In these example implementations, during a scan of the surface of the substrate W the processor 470 controls the non-rotatable substrate table 410 to move in the positive and negative x-directions and in the positive and negative y-directions.

Alternatively or additionally, the movement mechanism 430 is coupled to a radiation source 490 which emits the radiation beam 422, and the processor 470 is configured to control the movement mechanism 430 to control movement of the radiation source 490 to move the measurement location MLO.

Alternatively or additionally, the movement mechanism 430 is coupled to the projection optics 420, and the processor 470 is configured to control the movement mechanism 430 to control movement of the projection optics 420 to move the measurement location MLO.

Thus, in one example, the processor 470 is configured to control the movement mechanism 430 to move the non-rotatable substrate table 410 so as to move the substrate W supported by the non-rotatable substrate table 410 through the measurement location MLO, and the radiation source 490 and the projection optics 420 remains in a fixed position.

The detection optics 440 are operable to receive a portion 442 of the radiation beam reflected from the substrate W. The detection optics 440 is generally equivalent to the detection unit LSD shown in FIG. 2 and described above. The detection optics 440 comprise second imaging optics 449 and a detection grating 448. The second imaging optics are arranged to receive the reflected radiation 442.

An image of the projection patterning device 424 is formed on the detection grating 448, the position of that image being indicative of a height of the substrate W. In particular, a position of that image relative to the detection grating 448 is indicative of a height of the substrate W. The detection grating 448 may have a periodicity which corresponds with a periodicity of a grating image formed by the reflected radiation 442. The detection grating 448 directs radiation to the detector 450. The detector 450 produces a detector output signal indicative of the light received, for example indicative of the intensity of the light received, such as may be output by a photodetector, or representative of a spatial distribution of the intensity received, such as may be output by a camera or sensor array. The detector 450 may comprise any combination of one or more detector types.

A processor 470 receives the detector output signal from the detector 450 and is operable to determine a height of the substrate W. These techniques are known to persons skilled in the art and are thus not discussed in detail herein. FIG. 4 shows a single processor 470 that is configured to control the movement mechanism 430 and also determine the height of the surface on the substrate based on the detector output signal received from the detector 450. This is merely an example. In other examples, a first processor 470 is configured to control the movement mechanism 430 and a separate second processor 470 is configured to determine the height of the surface on the substrate based on the detector output signal received from the detector 450.

Some embodiments of the present disclosure relate to a method of mapping the height of a surface on a substrate as now discussed with reference to FIG. 5.

FIG. 5 illustrates a method 500 of mapping the height of a surface on a substrate (e.g. measuring a topography of the surface). The method 500 may, for example, be carried out using the apparatus 400.

The method 500 comprises a step S502 of controlling the movement mechanism 430 to generate a single stroke of movement of the measurement location MLO of a plurality of measurement spots of the radiation beam 422 over the surface of a substrate W.

In embodiments whereby the movement mechanism 430 is coupled to the non-rotatable substrate table 410, step S502 may comprise controlling the movement mechanism 430 to move the non-rotatable substrate table 410 so as to move the substrate W supported by the non-rotatable substrate table 410 through the measurement location MLO.

In embodiments whereby the movement mechanism 430 is coupled to the radiation source 490 which emits the radiation beam 422, step S502 may comprise controlling the movement mechanism 430 to control movement of the radiation source 490 to move the measurement location MLO.

In embodiments whereby the movement mechanism 430 is coupled to the projection optics 420, step S502 may comprise controlling the movement mechanism 430 to control movement of the projection optics 420 to move the measurement location MLO.

FIG. 6 is a top view of an upper surface of a substrate W, and depicts a measurement location MLO comprising a plurality of measurement spots 600. As shown in FIG. 6, the plurality of measurement spots 600 may be arranged in a line. The measurement location MLO is where the beam of radiation 422 is incident on the surface of a substrate W. During step S502, instead of parallel scan strokes in the y-direction, the movement mechanism 430 is controlled to generate a single stroke of movement of the measurement location MLO in a plane of the substrate W with the stroke following a curved path to map the entire surface of the substrate W during the single stroke.

The polar co-ordinates of the curved path may have an angle component which monotonically increases during the stroke. Similarly, the polar co-ordinates of the curved path may have an angle component which monotonically decreases during the stroke. In some embodiments, the movement mechanism 430 is controlled to generate a single stroke of movement of the measurement location MLO in a plane of the substrate W with the stroke following a continually curved path to map the entire surface of the substrate W during the single stroke. In other embodiments, the stroke follows a curved path which is curved along the majority of the path. For example, the curved path may be curved along at least 80% of the path, optionally at least 90% of the path, optionally at least 95% of the path. That is, a (minority) fraction of the trajectory of the measurement location MLO may be linear. We refer below to different examples that the trajectory of the measurement location MLO may take. The movement mechanism 430 may be controlled such that a trajectory is defined by piecewise polynomial approximation, also known as splines.

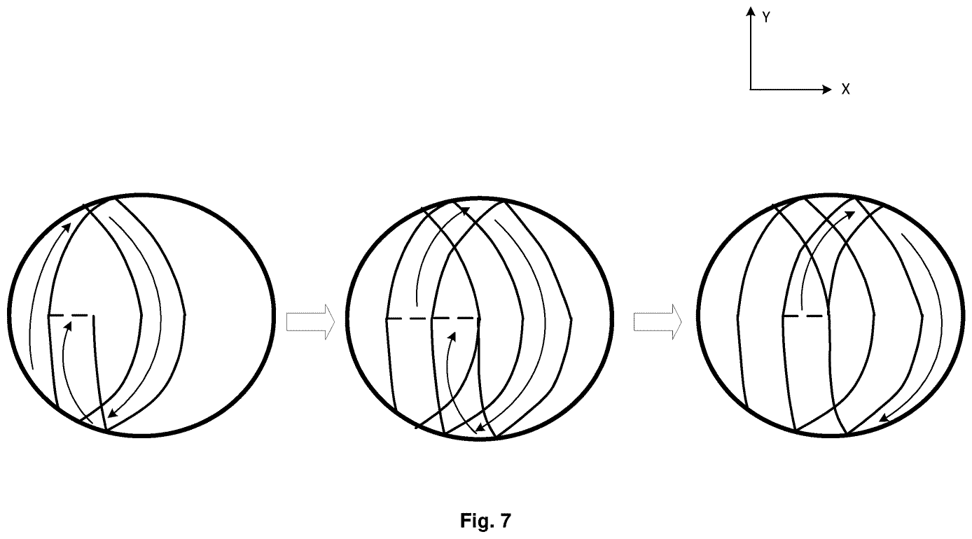

FIG. 7 illustrates an example path taken by the measurement location MLO of the plurality of measurement spots of the radiation beam 422, over the surface of the substrate W during step S502.

As can be seen in FIG. 7, the movement mechanism 430 is controlled such that polar co-ordinates of the curved path has a pole which moves in the x-direction whilst the surface of the substrate W is being scanned during step S502. As shown in FIG. 7, the scan commences with the measurement location MLO positioned at an outer edge of the substrate W and follows a clockwise curved path (e.g. a continually curved path). Whilst a clockwise curved path is shown in FIG. 7, it will be appreciated that the scan may commence with the measurement location MLO positioned at an outer edge of the substrate W and follow an anti-clockwise curved path (e.g. a continually curved path).

In the example of FIG. 7, regions of the measured topography overlap where the direction of the scan changes from being in the positive y-direction to the negative y-direction. Sampling of the topography in this manner advantageously increases the accuracy of the topography reconstruction due to the denser and more overlapping sampling results.

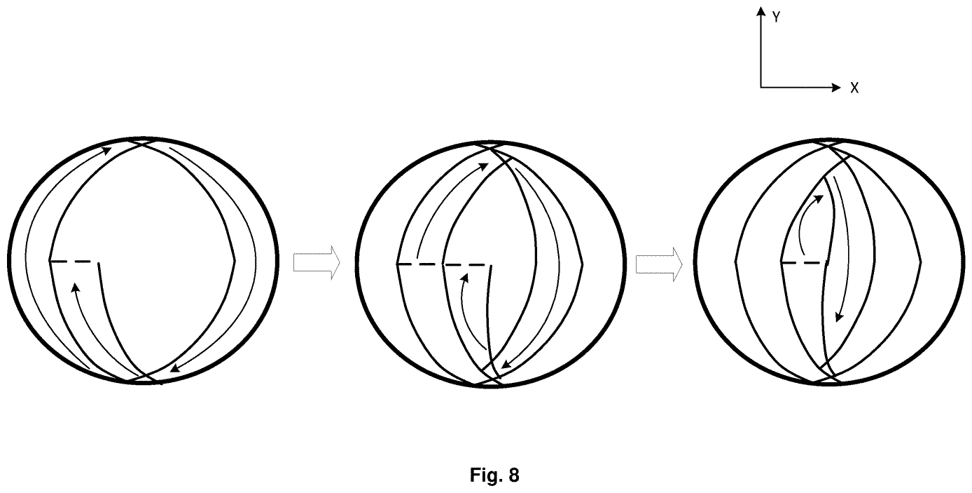

FIG. 8 illustrates another example path taken by the measurement location MLO of the plurality of measurement spots of the radiation beam 422, over the surface of the substrate W during step S502.

As can be seen in FIG. 8, the movement mechanism 430 is controlled such that the measurement location follows a spiral path. As shown in FIG. 8, the scan commences with the measurement location MLO positioned at an outer edge of the substrate W and spirals radially inwards towards a substantially central location on the surface of the substrate. It can be seen that the spiral scan is carried out with minimal overlap at the points where the scan changes y-direction, and instead begins the scan around the outer circumference of the substrate, continuing the scan by spiraling radially inwards towards a substantially central location until the wafer topography is scanned in its entirety. This minimizes the time taken to scan the entire surface of the substrate W (e.g. compared to when the measurement location MLO takes the path shown in FIG. 7).

Whilst a clockwise curved path is shown in FIG. 8, it will be appreciated that the scan may commence with the measurement location MLO positioned at an outer edge of the substrate W and follow an anti-clockwise curved path spiraling radially inwards.

Furthermore, the scan may commence with the measurement location MLO originating at a substantially central location on the surface of the substrate and may spiral radially outwards (in a clockwise or anti-clockwise direction) towards an edge of the substrate.

As can be seen from both FIGS. 7 and 8, advantageously no time is spent scanning outside of the boundary of the substrate W.

In both examples, the map of the substrate is measured as a single stroke that can be fully measured during control of the movement mechanism 430. This means that there are no scan-in set points for consecutive strokes that are computed by extrapolation of the data at the end of the preceding stroke. This will make the map of the substrate more robust.

In both examples, the curved path results in the field-to-field repeating product topography (the product topography or height pattern of every exposure field will be almost equal, due to manufacturing process of the preceding layers of the device that is being made) being sampled at many more locations. This advantageously enables a more accurate reconstruction of the topography of the substrate.

In some embodiments the single stroke, which maps the substrate and constitutes a scan, may begin and/or end outside the edge boundary area of a substrate.

Known techniques such as those shown in FIG. 3 typically require an additional measurement scan horizontally across the substrate to be able to deal with “process dependent spot offsets” of the plurality of measurement spots 600 (caused by the slightly different optical characteristics of each measurement spot which interacts with the properties of the substrate). As noted above the substrate may be a resist coated wafer. The aim of the level sensor is to measure the height of the resist layer on top of the wafer, but due to partial penetration of the level sensor radiation into the stack of material below the resist the signal is somewhat influenced by the stack of materials of the IC-in-the-making that is on the wafer. This effect is what is referred to herein as “process dependent spot offsets”. The part of the process dependent level sensor spot offsets that is common for all individual spots of the level sensor will result in single height offset (error) of the measured wafer map. This can be compensated for by exposing for instance a Focus/Exposure Matrix (FEM) on a product wafer. This is exposing (a meander of) fields with different height offsets. By comparing the printed device features in the fields with different height offsets it is possible to determine which is the best offset to compensate for height errors (one of them being the level sensor process dependent height offset that is common for all spots). The process dependent spot-to-spot delta offset errors of the level sensor can be calibrated (in case of layout independent leveling) by means of a horizontal scan (e.g. in the x direction) across the wafer. The determined spot to spot delta offset errors are used to correct the individual level sensor spot, such that the remaining process dependent offset errors of the level sensor are predominantly the same for all spots, and the FEM can be used to compensate for it. With the paths shown in FIGS. 7 and 8 there is enough redundancy in the data (in particular from the scan of near the top and bottom of the wafer where regions of the measured topography overlap) to be able to compute the process dependent spot offsets and avoid the need for the additional measurement scan.

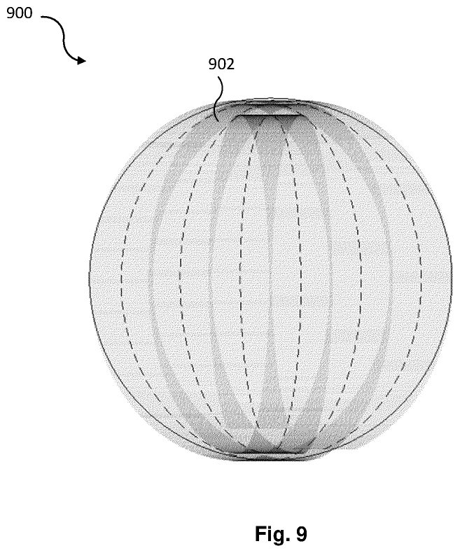

FIG. 9 illustrates a non-uniform radiation dose from the radiation beam 422 on a surface of the substrate W after the entire surface has been mapped using a continually curved spiral path as shown in FIG. 8. The continually curved spiral path taken by the single stroke of movement of the measurement location MLO over the surface of the substrate is shown with the dashed line . The dose map shown in FIG. 9 reflects the total dose of light that has come from the level sensor during the measurement of the entire substrate W. FIG. 9 illustrates that there are portions of the substrate W (e.g. near the top and bottom of the substrate W) where the sampling is denser with more overlap/redundancy. This non-uniform radiation dose is also experienced after the entire surface has been mapped using the curved path shown in FIG. 7.

During step S502, the movement mechanism may be controlled to move the measurement location MLO over the surface of the substrate with non-constant velocity and non-constant acceleration during the single stroke of movement of the measurement location MLO over the surface of the substrate W. For example, in the example described above whereby the processor 470 is configured to control the movement mechanism 430 to move the non-rotatable substrate table 410 so as to move the substrate W supported by the non-rotatable substrate table 410 through the measurement location MLO, and the radiation source 490 and the projection optics 420 remains in a fixed position, the non-rotatable substrate table 410 may move with non-constant velocity and non-constant acceleration during the single stroke of movement of the measurement location MLO over the surface of the substrate W.

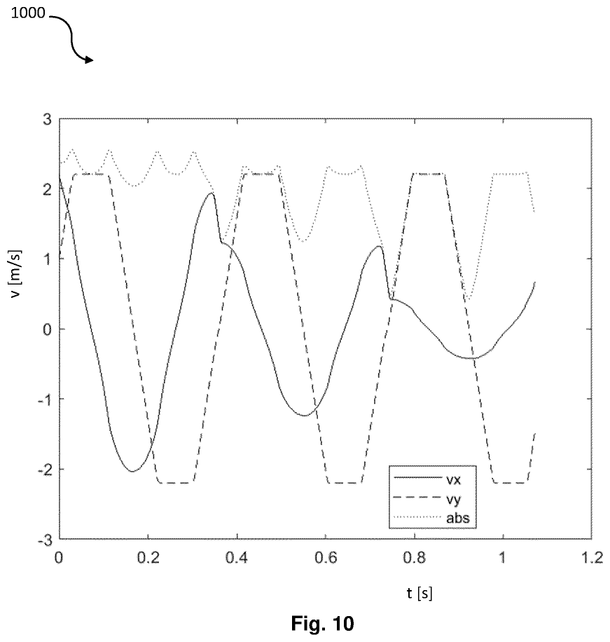

FIG. 10 depicts the non-constant velocity of the measurement location over the surface of a substrate during a scan of the substrate. In particular, FIG. 10 illustrates the non-constant velocity ‘vx’ in the x-direction (in the plane of the substrate), the non-constant velocity ‘vy’ in the y-direction (in the plane of the substrate), and the absolute velocity ‘abs’ in the actual scan direction (the length of the vector [vx, vy]).

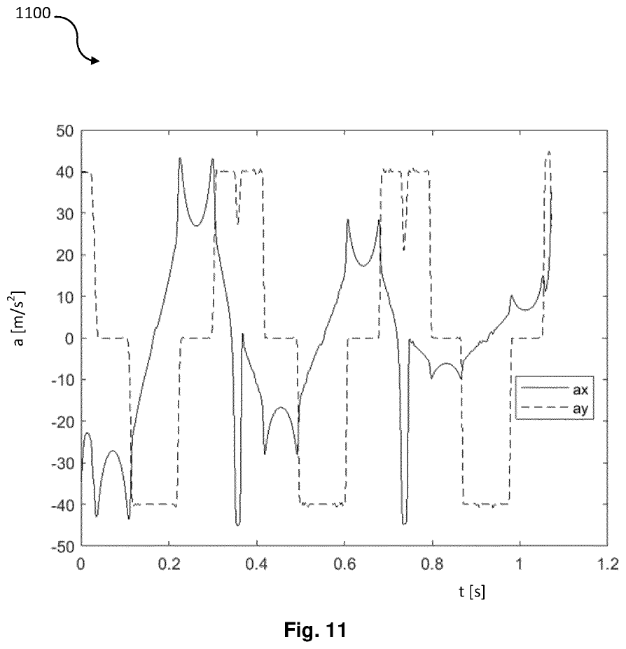

FIG. 11 depicts the non-constant acceleration of the measurement location over the surface of a substrate during a scan of the substrate. In particular, FIG. 11 illustrates the non-constant acceleration ‘ax’ in the x-direction (in the plane of the substrate), and the non-constant acceleration ‘ay’ in the y-direction (in the plane of the substrate).

The acceleration of the non-rotatable substrate table 410 may deform the non-rotatable substrate table 410 during the scanning process and such deformations may influence results of the measurement. Fortunately, this deformation is expected to be reproducible and therefore can be taken into account as a calibration step when mapping the height of a surface on a substrate.

Referring back to FIG. 5, the method 500 may further comprise a step S504 of receiving sensor data obtained by the level sensor during the single stroke of movement of the measurement location; and a step S506 of determining the height of the surface on the substrate based on the sensor data. Thus it can be seen that the level sensor constantly (without interruption) measures the entire surface of the substrate during the single stroke of movement of the measurement location.

In some embodiments, a single processor 470 may perform all of the steps of the method 500. In other embodiments, a first processor 470 may perform step S502, and a separate second processor 470 may perform steps S504 and S506. In both variants, a processor 470 receives the detector output signal from the detector 450 at step S504 and uses the detector output signal received to determine the height of the surface on the substrate at step S506. It will be appreciated that determining the height of the substrate W comprises determining a height of the substrate relative to a reference height or position, as is known in the art. The determining the height of the surface on the substrate performed at step S506 may be based on predetermined substrate deformation correction data to account for deformation of the non-rotatable substrate table 410 during the scanning process.

The substrate W referred to herein may be a substrate W within a lithographic apparatus LA. Such a substrate W may comprise a silicon wafer coated with a photoresist. The silicon wafer may comprise one or more layers than have previously been formed, for example using a lithographic process. In general, there will be a range of different materials and/or different densities of features across a surface of such wafers W. This can lead to changes in the reflectivity of the wafer W across its surface as different materials may absorb different fractions of the incident radiation and different densities of features can result in different amounts of scattering of the incident radiation. For example, 3D-NAND wafers may contain features that can give rise to up to a 50% reduction in the amount of specular reflection of radiation.

The method 500 may be used in a subsequent lithographic exposure method. The lithographic exposure method may comprise mapping the height of a surface on a substrate using the method 500 of FIG. 5. The lithographic exposure method may further comprise: patterning a radiation beam using a patterning device; projecting the patterned radiation onto the substrate W so as to form an image of the patterning device on the substrate; and controlling a position of the substrate W (while the patterned radiation is being projected onto the substrate W) in dependence on the measured topography of the surface of the substrate W (as measured using the method 500).

Advantageously, the measured topography of a surface of a substrate can be used to control a height of the substrate W while it is being exposed to the patterned radiation, for example to keep the substrate W in a plane of best focus for the image of the patterning device. It will be appreciated that the image of the patterning device formed on the substrate W may be a diffraction limited image.

Advantageously, topography measurement according to the invention in a “multiple stage” machine may benefit from reduced crosstalk between substrate supports, due to smoother wafer stage profiles and a shorter length of strokes in e.g. the y-direction. Reduced crosstalk is beneficial for overlay performance and may further increase speed of wafer map measurement.

The path length of a curved trajectory according to the invention is shorter than those of known techniques. The amount of work is the path integral of the force. As such, a further advantage of the invention is that a curved wafermap trajectory according to the invention reduces the energy required by the substrate support relative to known techniques.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

Although specific reference may have been made above to the use of embodiments of the invention in the context of optical lithography, it will be appreciated that the invention, where the context allows, is not limited to optical lithography and may be used in other applications, for example imprint lithography.

Where the context allows, embodiments of the invention may be implemented in hardware, firmware, software, or any combination thereof. Embodiments of the invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below. Other aspects of the invention are set out as in the following numbered clauses.
1. A method of mapping the height of a surface on a substrate, the method comprising: controlling a movement mechanism to generate a single stroke of movement of a measurement location of a plurality of measurement spots of a radiation beam over the surface of the substrate, the substrate supported by a non-rotatable substrate table, wherein the movement is in a plane of the substrate, the plurality of measurement spots are incident on the surface of the substrate by a level sensor for mapping the height of the substrate, and said stroke follows a curved path to map the entire surface of the substrate.
2. The method of clause 1, wherein the method comprises controlling the movement mechanism so that the measurement location follows a spiral path.
3. The method of clause 1 or 2, wherein the method comprises controlling the movement mechanism so that the measurement location originates from an edge of the substrate and spirals radially inwards towards a substantially central location on the surface of the substrate.
4. The method of clause 1 or 2, wherein the method comprises controlling the movement mechanism so that the measurement location originates from a substantially central location on the surface of the substrate and spirals radially outwards towards an edge of the substrate.
5. The method of clause 1, wherein the method comprises controlling the movement mechanism so that polar co-ordinates of the curved path has a pole which moves along an axis along the plane of the substrate.
6. The method of any preceding clause, wherein polar co-ordinates of the curved path has an angle component which monotonically increases or decreases during the stroke.
7. The method of any preceding clause, wherein the method comprises controlling the movement mechanism to move the measurement location over the surface of the substrate with non-constant velocity and non-constant acceleration during the stroke.
8. The method of any preceding clause, wherein the movement mechanism is coupled to the non-rotatable substrate table, the method comprising controlling the movement mechanism to control movement of the non-rotatable substrate table to move the measurement location.
9. The method of any preceding clause, wherein the movement mechanism is coupled to a radiation source which emits the radiation beam, the method comprising controlling the movement mechanism to control movement of the radiation source to move the measurement location.
10. The method of any preceding clause, wherein the movement mechanism is coupled to projection optics operable to form the plurality of measurement spots, the method comprising controlling the movement mechanism to control movement of the projection optics to move the measurement location.
11. The method of any preceding clause, wherein a radiation dose from the radiation beam on the surface of the substrate after the entire surface has been mapped is non-uniform.
12. The method of any preceding clause, the method comprising:
receiving sensor data obtained by the level sensor during the movement of the measurement location; and
determining the height of the surface on the substrate based on the sensor data.
13. The method of clause 11, wherein determining the height of the surface on the substrate based on the sensor data comprises modifying the sensor data based on predetermined substrate deformation correction data.
14. The method of any preceding clause, wherein the plurality of measurement spots are arranged in a line.
15. The method of any preceding clause, wherein said stroke follows a continually curved path.
16. An apparatus for mapping the height of a surface on a substrate, the apparatus comprising:
   a non-rotatable support table for supporting a substrate;
   projection optics arranged to direct a radiation beam to be incident on the surface of the substrate
   a movement mechanism controllable to generate a single stroke of movement of a measurement location of a plurality of measurement spots of the radiation beam over the surface of the substrate, and
   at least one processor configured to control the movement mechanism to generate the single stroke of movement of the measurement location, wherein the movement is in a plane of the substrate, and said stroke follows a curved path to map the entire surface of the substrate.
17. The apparatus of clause 16, wherein the at least one processor is configured to control the movement mechanism so that the measurement location follows a spiral path.
18. The apparatus of clause 16 or 17, wherein the at least one processor is configured to control the movement mechanism so that the measurement location originates from an edge of the substrate and spirals radially inwards towards a substantially central location on the surface of the substrate.
19. The apparatus of clause 16 or 17, wherein the at least one processor is configured to control the movement mechanism so that the measurement location originates from a substantially central location on the surface of the substrate and spirals radially outwards towards an edge of the substrate.
20. The apparatus of clause 16, wherein the at least one processor is configured to control the movement mechanism so that polar co-ordinates of the curved path has a pole which moves along an axis along the plane of the substrate.
21. The apparatus of any of clauses 16 to 20, wherein polar co-ordinates of the curved path has an angle component which monotonically increases or decreases during the stroke.
22. The apparatus of any of clauses 16 to 21, wherein the at least one processor is configured to control the movement mechanism to move the measurement location over the surface of the substrate with non-constant velocity and non-constant acceleration during the stroke.
23. The apparatus of any of clauses 16 to 22, wherein the movement mechanism is coupled to the non-rotatable substrate table, and the at least one controller is configured to control the movement mechanism to control movement of the non-rotatable substrate table to move the measurement location.
24. The apparatus of any of clauses 16 to 23, wherein the movement mechanism is coupled to a radiation source which emits the radiation beam, and the at least one processor is configured to control the movement mechanism to control movement of the radiation source to move the measurement location.
25. The apparatus of any of clauses 16 to 24, wherein the movement mechanism is coupled to projection optics operable to form the plurality of measurement spots, and the at least one processor is configured to control the movement mechanism to control movement of the projection optics to move the measurement location.
26. The apparatus of any of clauses 16 to 25, wherein a radiation dose from the radiation beam on the surface of the substrate after the entire surface has been mapped is non-uniform.
27. The apparatus of any of clauses 16 to 26, further comprising:
   detection optics operable to receive a portion of the radiation beam reflected from the substrate;
   a detector arranged to determine an intensity of the portion of the radiation beam;
wherein the at least one processor is configured to:
receive sensor data obtained by the detector during the movement of the measurement location; and
determine the height of the surface on the substrate based on the sensor data.
28. The apparatus of clause 27, wherein the at least one processor is configured to determine the height of the surface on the substrate based on the sensor data by modifying the sensor data based on predetermined substrate deformation correction data.
29. The apparatus of any of clauses 16 to 28, wherein the plurality of measurement spots are arranged in a line.
30. The apparatus of any of clauses 16 to 29, wherein said stroke follows a continually curved path.
31. The apparatus of any of clauses 16 to 30, further comprising a radiation source operable to produce the radiation beam.
32. A lithographic apparatus comprising the apparatus of any one of clauses 16 to 31.

1.-15. (canceled)

16. A method of mapping the height of a surface on a substrate, the method comprising:
controlling a movement mechanism to generate a single stroke of movement of a measurement location of a plurality of measurement spots of a radiation beam over the surface of the substrate, the substrate supported by a non-rotatable substrate table,
wherein the movement is in a plane of the substrate,
wherein the plurality of measurement spots are incident on the surface of the substrate by a level sensor for mapping the height of the substrate,
wherein the stroke follows a curved path to map the entire surface of the substrate,
wherein polar coordinates of the curved path has a pole that moves along an axis along the plane of the substrate during the stroke, and
wherein the polar coordinates of the curved path has an angle component that monotonically increases or decreases during the stroke.

17. The method of claim 16, wherein the controlling comprises controlling the movement mechanism so that the measurement location follows a spiral path.

18. The method of claim 16, wherein the controlling comprises controlling the movement mechanism so that:
the measurement location either originates from an edge of the substrate and spirals radially inwards towards a substantially central location on the surface of the substrate, or
the measurement location originates from a substantially central location on the surface of the substrate and spirals radially outwards towards an edge of the substrate.

19. The method of claim 16, wherein the controlling comprises controlling the movement mechanism to move the measurement location over the surface of the substrate with non-constant velocity and non-constant acceleration during the stroke.

20. The method of claim 16, wherein:
the movement mechanism is coupled to the non-rotatable substrate table, and
the controlling comprises controlling the movement mechanism to control movement of the non-rotatable substrate table to move the measurement location.

21. The method of claim 16, wherein:
the movement mechanism is coupled to a radiation source that emits the radiation beam, and
the controlling comprises controlling the movement mechanism to control movement of the radiation source to move the measurement location.

22. The method of claim 16, wherein:
the movement mechanism is coupled to projection optics operable to form the plurality of measurement spots, and
the controlling comprises controlling the movement mechanism to control movement of the projection optics to move the measurement location.

23. The method of claim 16, further comprising:
receiving sensor data obtained by the level sensor during the movement of the measurement location; and
determining the height of the surface on the substrate based on the sensor data.

24. The method of claim 16, wherein the stroke follows a continually curved path.

25. An apparatus configured to map a height of a surface on a substrate, the apparatus comprising:
a non-rotatable support table configured to support a substrate;
projection optics arranged to direct a radiation beam to be incident on the surface of the substrate;
a movement mechanism configured to generate a single stroke of movement of a measurement location of a plurality of measurement spots of the radiation beam over the surface of the substrate; and
at least one processor configured to control the movement mechanism to generate the single stroke of movement of the measurement location,
wherein the movement is in a plane of the substrate,
wherein the stroke follows a curved path to map the entire surface of the substrate,
wherein polar coordinates of the curved path have a pole that moves along an axis along the plane of the substrate during the stroke, and
wherein the polar coordinates of the curved path have an angle component that monotonically increases or decreases during the stroke.

26. The apparatus of claim 25, wherein the at least one processor is configured to control the movement mechanism so that:
the measurement location either originates from an edge of the substrate and spirals radially inwards towards a substantially central location on the surface of the substrate, or
the measurement location originates from a substantially central location on the surface of the substrate and spirals radially outwards towards an edge of the substrate.

27. The apparatus of claim 25, wherein the at least one processor is configured to control the movement mechanism to move the measurement location over the surface of the substrate with non-constant velocity and non-constant acceleration during the stroke.

28. The apparatus of claim 25, wherein:
the movement mechanism is coupled to the non-rotatable substrate table, and
the at least one controller is configured to control the movement mechanism to control movement of the non-rotatable substrate table to move the measurement location.

29. The apparatus of claim 25, wherein:
the movement mechanism is coupled to a radiation source that emits the radiation beam, and
the at least one processor is configured to control the movement mechanism to control movement of the radiation source to move the measurement location.

30. The apparatus of claim 25, wherein:
the movement mechanism is coupled to projection optics operable to form the plurality of measurement spots, and
the at least one processor is configured to control the movement mechanism to control movement of the projection optics to move the measurement location.
